(19) United States
(12) Patent Application Publication
(10) Pub. No.: US 2013/0216800 A1
(43) Pub. Date: Aug. 22, 2013

(54) PEROVSKITE TO BROWNMILLERITE COMPLEX OXIDE CRYSTAL STRUCTURE TRANSFORMATION INDUCED BY OXYGEN DEFICIENT GETTER LAYER

(71) Applicants: Joel D. Brock, Ithaca, NY (US); David A. Muller, Ithaca, NY (US); Lena Fitting Kourkoutis, Ithaca, NY (US); Arthur R. Woll, Ithaca, NY (US); John Ferguson, Ithaca, NY (US)

(72) Inventors: Joel D. Brock, Ithaca, NY (US); David A. Muller, Ithaca, NY (US); Lena Fitting Kourkoutis, Ithaca, NY (US); Arthur R. Woll, Ithaca, NY (US); John Ferguson, Ithaca, NY (US)

(21) Appl. No.: 13/522,997

(22) PCT Filed: Jan. 19, 2011
(86) PCT No.: PCT/US11/21617

§ 371 Date: Sep. 13, 2012

Related U.S. Application Data
(60) Provisional application No. 61/296,990, filed on Jan. 21, 2010.

(51) Int. Cl. C30B 29/68; C30B 25/02; C30B 28/14; C23C 16/40

(52) U.S. Cl. CPC C30B 29/68; C23C 16/40; C30B 25/02; C30B 28/14
USPC 428/213; 427/255.31; 117/103; 428/697

(57) ABSTRACT

A method for forming a heterostructure includes forming a first perovskite crystal structure complex oxide material layer over a substrate to a first thickness. A second perovskite crystal structure oxygen deficient complex oxide oxygen getter material layer is formed upon the first perovskite crystal structure complex oxide material layer. When the second perovskite crystal structure oxygen deficient complex oxide oxygen getter material layer reaches a critical thickness that may approximate one-half to one times the first thickness, the first perovskite crystal structure complex oxide material layer spontaneously transforms into a first brownmillerite crystal structure complex oxide material layer, with an attendant transfer of substantially one-half oxygen atom per perovskite unit cell to the second perovskite crystal structure oxygen deficient complex oxide oxygen getter material layer, thus forming a second perovskite crystal structure oxygen enriched complex oxide oxygen getter material layer. A particular heterostructure derives from the foregoing methodology.

### CROSS-REFERENCE TO RELATED APPLICATION

This application is related to Application Ser. No. 61/296,990, filed 21 Jan. 2010 and titled “Epitaxial Getter Layer for Complex Oxide Brownmillerite Phase Transformation,” the contents of which is incorporated herein fully by reference.

### STATEMENT OF GOVERNMENT INTEREST

The research that lead to this invention was funded by the U.S. Government under: (1) Project ID DMR-0317729 to the Cornell Center for Materials Research; and (2) Project ID DMR-0225180 to the Cornell High Energy Synchrotron Source. The U.S. Government has rights in this invention.

### BACKGROUND

1. Field of the Invention

The invention relates generally to complex oxide materials. More particularly, the invention relates to crystal structure transformation within complex oxide materials.

2. Description of the Related Art

Many complex oxide materials that have a perovskite crystal structure (i.e., correlating with an ABO₃ composition) also have a corresponding oxygen deficient crystal structure where an oxygen vacancy reordering may occur. A particular corresponding crystal structure resulting from such an oxygen vacancy reordering of the perovskite crystal structure is a brownmillerite crystal structure (i.e., correlating with an A₂B₂O₅ composition). When forming a brownmillerite crystal structure complex oxide material from a perovskite crystal structure complex oxide material, one-half an oxygen atom per perovskite crystal structure unit cell is transferred in conjunction with the oxygen vacancy reordering.

Complex oxide materials that possess the brownmillerite crystal structure are of interest since they often possess a high degree of solid state ionic conductivity, in addition to other enhanced materials properties that may include, but are not necessarily limited to, enhanced magnetic material properties. Such enhanced solid state ionic conductivity may lead to application of brownmillerite crystal structure complex oxide materials in solid oxide fuel cells, oxygen sensors and other related devices.

Due to their unique and often superior materials properties that are of continuing interest and potential commercial importance, methods and materials for forming stable brownmillerite crystal structure complex oxide materials are desirable.

### SUMMARY OF THE INVENTION

Embodiments of the invention include: (1) a heterostructure including a brownmillerite crystal structure complex oxide material layer; and (2) a method for forming the heterostructure including the brownmillerite crystal structure complex oxide material layer.

The heterostructure in accordance with the embodiments comprises the brownmillerite crystal structure complex oxide material layer located over a substrate and having a substantially A₂B₂O₅ composition. The heterostructure also includes a perovskite crystal structure oxygen enriched complex oxide oxygen getter material layer located upon the brownmillerite crystal structure complex oxide material layer and having an A′B′O_{3-δ′} composition, where 3−δ′ is in a range from about 1.5 to about 3.0.

The method for forming the foregoing heterostructure in accordance with the embodiments includes forming a perovskite crystal structure complex oxide material layer over a substrate to a first thickness, and then forming upon the perovskite crystal structure complex oxide material layer a perovskite crystal structure oxygen deficient complex oxide material layer which serves as an oxygen getter layer. The perovskite crystal structure complex oxide material layer has an ABO₃ composition and the perovskite crystal structure oxygen, deficient complex oxide oxygen getter material layer has an A′B′O_{3-δ} composition, where 3−δ is in a range from about 1.0 to about 2.5 (i.e., as low as about 1.0 to about 1.5, or about 1.0 to about 2.0), alternatively from about 1.5 to about 2.5 and further alternatively from about 2.0 to about 2.5. The perovskite crystal structure oxygen deficient complex oxide oxygen getter material layer is formed to a second thickness sufficient (i.e., experimentally determined as typically but not necessarily correlating with: (1) about one-half to about one times the first thickness of the perovskite crystal structure complex oxide material layer at initiation; and (2) about three-quarters to about two times the first thickness of the perovskite crystal structure complex oxide material layer at completion) to spontaneously extract substantially one-half oxygen atom per perovskite unit cell from the perovskite crystal structure complex oxide material layer and form therefrom: (1) a brownmillerite crystal structure complex oxide material layer having a substantially A₂B₂O₅ composition; in turn having formed thereupon (2) the perovskite crystal structure oxygen enriched complex oxide oxygen getter material layer having the ABO_{3-δ′} composition, where 3-δ′, as above, is in the range, from about 1.5 to about 3.0 (i.e., as low as about 1.5 to about 2.0, or about 1.5 to about 2.5), alternatively from about 2.0 to about 3.0 and further alternatively from about 2.5 to about 3.0.

A particular exemplary non-limiting heterostructure in accordance with the embodiments includes a substrate. In an aspect, the heterostructure also includes a brownmillerite crystal structure first complex oxide material layer of composition substantially A₂B₂O₅ located upon the substrate. In an aspect, the heterostructure also includes a perovskite crystal structure second complex oxide material layer of composition A′B′O_{3-δ′} located upon the first complex oxide material layer, where 3−δ′ is in a range from about 1.5 to about 3.0.

A particular exemplary non-limiting method for forming a heterostructure in accordance with the embodiments includes forming over a substrate a perovskite crystal structure first complex oxide material layer having an ABO₃ composition and a first thickness. In an aspect, the method also includes forming upon the perovskite crystal structure first complex oxide material layer a perovskite crystal structure second complex oxide oxygen getter material layer having an A′B′O_{3-δ} composition, the perovskite crystal structure second complex oxide oxygen getter material layer having a second thickness such that substantially one-half oxygen atom per perovskite crystal structure unit cell of the first complex oxide material layer is spontaneously extracted from the first complex oxide material layer to form: (1) a brownmillerite crystal structure first complex oxide material layer formed over the substrate and having a substantially A₂B₂O₅ composition; and (2) an oxygen enriched perovskite crystal structure second complex oxide oxygen getter material layer formed upon the brownmillerite crystal structure first complex oxide material layer and having an A′B′ O_{3-δ′} composition, where 3−δ′ is greater than 3−δ.

Within the embodiments as described and the invention as claimed, the A₂B₂O₅ composition of the brownmillerite crystal structure first complex oxide material layer is intended as and defined as a “substantially” A₂B₂O₅ composition which otherwise exhibits a brownmillerite crystal structure as may be determined in accordance with the experimental examples that follow. Such a “substantially” A₂B₂O₅ composition may in particular have, but is not necessarily limited to, a non-stoichiometric oxygen content to, provide nominal “substantially” A₂B₂O₅ compositions in a range from about A₂B₂O_{4.5} to about A₂B₂O_{5.5}. Also contemplated as included are narrower offset ranges that may include, but are not necessarily limited to: (1) a range from about A₂B₂O_{4.5} to about A₂B₂O_{4.8}, and (2) a range from about A₂B₂O_{5.2} to about A₂B₂O_{5.5}.

As is also understood by a person skilled in the art, a variation in an A₂B₂O₅ composition of the brownmillerite crystal structure first complex oxide material layer to provide the foregoing “substantially” A₂B₂O₅ composition also implies extraction of substantially one-half oxygen atom (with commensurately scaled variability) per perovskite unit cell incident to the perovskite to brownmillerite crystal structure transformation of the first complex oxide material layer.

In addition, while the embodiments that follow illustrate the invention within the context of a nominal or expected epitaxial deposition method for forming a heterostructure including a brownrnillerite crystal structure first complex oxide material layer, the embodiments are not intended to be so limited. Rather, the embodiments are intended to include fabrication methods other than those that are purely epitaxial growth methods which ultimately lead to a heterostructure that includes a brownmillerite crystal structure first complex oxide material layer within the context of the inventive claimed heterostructure or method. In accordance with the experimental examples that follow, certain thermal annealing methods in conjunction with epitaxial growth methods are anticipated as included within the embodiments. Other methodological variations are not precluded.

### BRIEF DESCRIPTION OF THE DRAWINGS

The objects, features and advantages of the invention are understood within the context of the Detailed Description of the Embodiments, as set forth below. The Detailed Description of the Embodiments is understood within the context of the accompanying drawings, which form a material part of this disclosure, wherein:

FIG. 1a, FIG. 1b, FIG. 1c and FIG. 1d show a series of schematic cross-sectional diagrams illustrating the results of progressive stages in forming a heterostructure in accordance with the embodiments that includes a brownmillerite crystal structure complex oxide material layer located and formed over a substrate.

FIG. 2a shows a graph of x-ray Intensity versus Time illustrating anti-Bragg reflected x-ray intensity oscillations when forming an LSMO/STO/LAO heterostructure including a brownmillerite crystal structure complex oxide material layer having the composition La_{0.7}Sr_{0.3}MnO_{2.5} from a corresponding perovskite crystal structure complex oxide material layer having the composition La_{0.7}Sr_{0.3}MnO_{3.0} in accordance with an, experimental example of the embodiments.

FIG. 2b shows a graph of x-ray Intensity versus K illustrating post deposition reflected x-ray intensity of the heterostructure formed in accordance with FIG. 2a.

FIG. 3 shows a crystal structure transformation diagram illustrating deposition conditions for an STO perovskite crystal structure complex oxide oxygen getter material layer that may be used to induce a brownmillerite crystal structure superlattice transformation within an underlying perovskite crystal structure complex oxide material layer within a heterostructure in accordance with the embodiments.

FIG. 4a shows a scanning transmission electron microscopy image of a heterostructure in accordance with the experimental examples of the embodiments.

FIG. 4b shows an idealized brownmillerite unit cell in comparison with an idealized perovskite unit cell in accordance with the experimental examples of the embodiments.

FIG. 5a shows a graph of x-ray Intensity versus Thickness illustrating anti-Bragg reflected x-ray intensity oscillations for deposition and perovskite crystal structure to brownmillerite crystal structure transformation of a plurality of manganite complex oxide material layers in accordance with the experimental examples of the embodiments.

FIG. 5b shows a graph of x-ray Intensity, versus K for each of the manganite complex oxide material layers in accordance with the experimental examples of the embodiments, further in accordance with FIG. 5a.

### DETAILED DESCRIPTION OF THE EMBODIMENTS

The objects, features and advantages of the invention are understood within the context of the detailed description of the embodiments, as set forth below. The detailed description of the embodiments as set forth below is understood within the context of the drawings described above. Since the drawings are intended for illustrative purposes, the drawings are not necessarily drawn to scale.

To assist in illustrating and understanding the embodiments, the detailed description set forth below will first illustrate and quantify a general perovskite crystal structure complex oxide material layer to brownmillerite crystal structure complex oxide material layer transformation phenomenon that provides the basis for, and comprises at least in-part, the embodiments. The detailed description set forth below will next illustrate the foregoing general crystal structure transformation phenomenon within the context of specific experimental exemplary data related in-part to a La_{0.7}Sr_{0.3}MnO_{3.0} perovskite crystal structure complex oxide material layer to La_{0.7}Sr_{0.3}MnO_{2.5} brownmillerite crystal structure complex oxide material layer crystal structure transformation in accordance with the embodiments. The embodiments are predicated upon a spontaneous perovskite crystal structure complex oxide material layer to brownmillerite crystal structure complex oxide material layer crystal structure transformation for a particular complex oxide material that is effected when depositing a perovskite crystal structure oxygen deficient complex oxide oxygen getter material layer upon a perovskite crystal structure complex oxide material layer formed of the particular complex oxide material. Such a perovskite crystal structure complex oxide material layer to brownmillerite crystal structure complex oxide material layer crystal structure transformation initiates when the perovskite crystal structure oxygen deficient complex oxide oxygen getter material layer reaches a second thickness experimentally determined (for at least some complex oxide material layer systems) as generally approximate to one-half to one times a first thickness of the perovskite crystal structure complex oxide material layer (i.e., as discussed below, each of the first thickness and the second thickness in generally measured in terms of crystal structure unit cell monolayers). In accordance with the foregoing crystal structure transformation, one-half oxygen atom per unit cell of the perovskite crystal structure complex oxide material layer transfers to the perovskite crystal structure oxygen deficient complex oxide oxygen getter material layer within the context of the spontaneous perovskite crystal structure complex oxide material layer to brownmillerite crystal structure complex oxide material layer transformation.

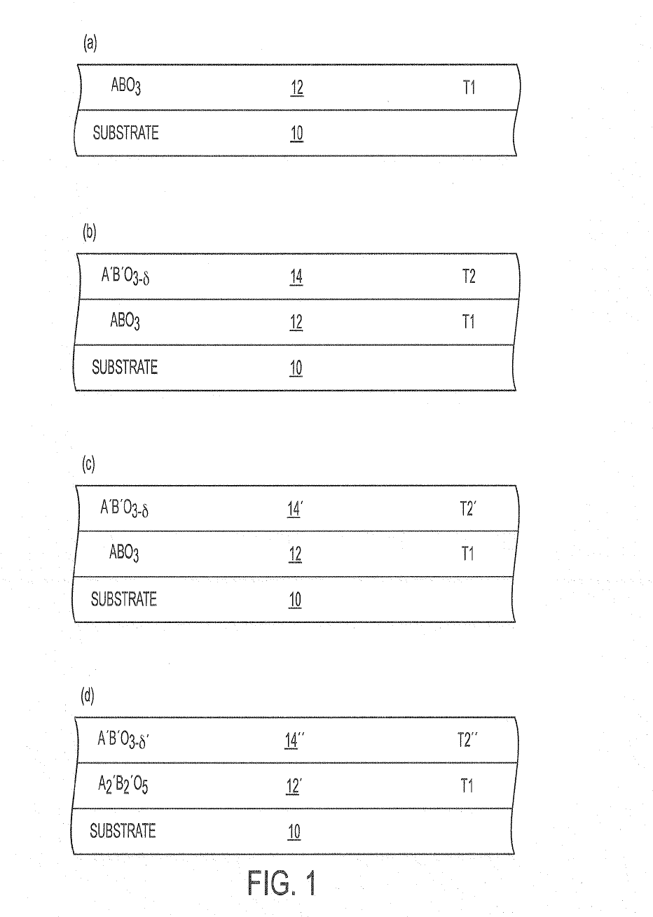

FIG. 1a, FIG. 1b, FIG. 1c and FIG. 1d show a series of schematic cross-sectional diagrams illustrating the results of progressive stages in forming a heterostructure that includes a brownmillerite crystal structure complex oxide material layer located and formed therein in accordance with the embodiments.

FIG. 1a in a first instance shows a substrate 10 upon which is located and formed a perovskite crystal structure complex oxide material layer 12 having an ABO₃ composition and a thickness T1.

Within the embodiments, the substrate 10 may comprise any of several materials upon, or over which a perovskite crystal structure complex oxide material layer may in general be formed. Thus, the substrate 10 itself may comprise a perovskite crystal structure complex oxide material, although such is not a limitation or requirement within the embodiments. Alternatively, the substrate 10 may comprise an amorphous or otherwise non-crystalline substrate material, or further alternatively a polycrystalline substrate material, or yet further alternatively a crystalline substrate material having a crystal structure other than a perovskite crystal structure. Typically and preferably, the substrate 10 comprises a perovskite crystal structure complex oxide material that has a thickness from about 0.1 to about 5 millimeters.

Within the embodiments, the perovskite crystal structure complex oxide material layer 12 has, as is illustrated in FIG. 1a, the composition ABO₃. Within the composition ABO₃, A and B are both metal cations and the size (i.e., ionic radius) of metal cation A is larger than the size (i.e., ionic radius) of metal cation B. Within the embodiments, B is selected as comprising at least one multivalent metal cation that allows for facile electron transfer and oxidation state change incident to a perovskite crystal structure to brownmillerite crystal structure transformation with respect to the perovskite crystal structure complex oxide material layer 12.

As is further illustrated in FIG. 1a, and as noted above, the perovskite crystal structure complex oxide material layer 12 has a first thickness T1, which will generally be at least about 4 monolayers (i.e., measured within the context of a perovskite unit cell monolayer (ML)), more preferably from about 12 to about 500 monolayers and most preferably from about 12 to about 80 monolayers. The foregoing monolayer thicknesses in general correspond with a perovskite crystal structure complex oxide material layer 12 thickness T1 at least about 1.5 nanometers, more preferably from about 5 to about 200 nanometers and most preferably from about 5 to about 30 nanometers.

FIG. 1b shows the initial results of deposition of a perovskite crystal structure oxygen deficient complex oxide oxygen getter material layer 14 having a composition A′B′O_{3-δ} located and formed upon the perovskite crystal structure complex oxide material layer 12 that is illustrated in FIG. 1a. Within the embodiments, the perovskite crystal structure oxygen deficient complex oxide oxygen getter material layer 14 will typically have a chemical composition exclusive of oxygen (i.e. A′ and B′) that is different in comparison with the perovskite crystal structure complex oxide material layer 12. In particular, the perovskite crystal structure oxygen deficient complex oxide oxygen getter material, layer 14 and the substrate 10 may desirably share the same A′ and B′ cation component elements, with: (1) the substrate 10 comprising an A′B′O₃ composition perovskite crystal structure complex oxide material; and (2) the perovskite crystal structure oxygen deficient complex oxide oxygen getter material layer 14 having the A′B′O_{3-δ} composition, where 3−δ is in a range from about 1.0 to about 2.5. However, the perovskite crystal structure oxygen deficient complex oxide oxygen getter material layer 14 and the substrate 10 need not have the same A′ and B′ cation components, which otherwise correlate with the A and B cation components within the perovskite crystal structure complex oxide material layer 12.

Within the embodiments, A′ and B′ are generally and desirably selected to provide the perovskite crystal structure oxygen deficient complex oxide oxygen getter material layer 14 that sustains and maintains a perovskite crystal structure over a broad range of oxygen content, and in particular at a low oxygen content at which other complex oxide materials may exist in a brownmillerite crystal structure or other oxygen deficient crystal structure. In accordance with experimental exemplary data discussed below, strontium titanate (STO) and lanthanum aluminate (LAO) complex oxide materials are candidate complex oxide materials for the perovskite crystal structure oxygen deficient complex oxide oxygen getter material layer 14, although other complex oxide materials are not excluded. Presumably, any perovskite crystal structure oxygen deficient complex oxide oxygen getter material layer 14 may be used such that the difference in oxygen affinity between the perovskite crystal structure complex oxide material layer 12 and the perovskite crystal structure oxygen deficient complex oxide oxygen getter material layer 14 drives the diffusion of oxygen into the perovskite crystal structure oxygen deficient complex oxide oxygen getter material layer 14. Particular additional candidate complex oxide material layer systems may be empirically determined absent undue experimentation.

Finally, FIG. 1b illustrates the perovskite crystal structure oxygen deficient complex oxide oxygen getter material layer 14 is located and formed upon the perovskite crystal structure complex oxide material layer 12 to a thickness T2. Within the context of the embodiments, the thickness T2 is intended to represent less than half the monolayers of the perovskite crystal structure oxygen deficient complex oxide oxygen getter material layer 14 in comparison with the monolayers of the perovskite crystal structure complex oxide material layer 12 as represented by T1.

FIG. 1c shows the same basic heterostructure that is illustrated in FIG. 1b, but wherein the perovskite crystal structure oxygen deficient complex oxide oxygen getter material layer 14 as illustrated in FIG. 1b is further deposited and formed to a second thickness T2′ that is greater than the second thickness T2, thus providing a perovskite crystal structure oxygen deficient complex oxide oxygen getter material layer 14′. When this second thickness T2′ approximates one-half to one times the first thickness T1 of the perovskite crystal structure complex oxide material layer 12, a spontaneous transformation of the perovskite crystal structure complex oxide material layer 12 and the perovskite crystal structure oxygen deficient complex oxide oxygen getter material layer 14′ is initiated to ultimately provide a heterostructure in accordance with FIG. 1d. While the thickness T2′ to initiate the spontaneous transformation may be approximated as one-half to one times T1, this particular thickness T2′ is anticipated to be materials selection and chemical kinetics dependent and thus may not necessarily be anticipated to be equivalent or identical for all complex metal oxide layer systems.

FIG. 1d shows the results of such a spontaneous transformation, which occurs incident to further deposition of the perovskite crystal structure complex oxide oxygen deficient oxygen getter material layer 14′ as is illustrated in FIG. 1 c to a thickness T2″ that is from about three-quarters to about two times the thickness T1 of the perovskite crystal structure complex oxide material layer 12. Such a spontaneous transformation in a first instance, provides that the perovskite crystal structure complex oxide material layer 12 has spontaneously completely transformed into a brownmillerite crystal structure complex oxide material layer 12′ having a composition substantially A₂B₂O₅ along with an attendant loss of a corresponding substantially 0.5 oxygen atoms per perovskite crystal structure unit cell. In conjunction with the loss of oxygen by the perovskite crystal structure complex oxide material layer 12 when fowling the brownmillerite crystal structure complex oxide material layer 12, the perovskite crystal structure oxygen deficient complex oxide oxygen getter material layer 4′ is simultaneously transformed into a perovskite crystal structure oxygen enriched complex oxide oxygen getter material layer 14″ that has a composition A′B′ O_{3-δ}′, where 3−δ′ is greater than 3−δ.

Within the context of the foregoing generalized description of the phenomenon that provides the basis of the embodiments, the perovskite crystal structure complex oxide material layer 12 and the perovskite crystal structure oxygen deficient complex oxide oxygen getter material layers 14 and 14′ may in general be formed using any of several methods. Included but not limiting are chemical vapor deposition methods and physical vapor deposition methods that may desirably be epitaxial methods and may also include, but are not necessarily limited to, pulsed laser deposition methods.

The perovskite crystal structure complex oxide material layer 12 and the perovskite crystal structure oxygen deficient complex oxide oxygen getter material layers 14, 14′ and 14″ may be formed using a epitaxial pulsed laser deposition method, although, as noted above, other deposition methods are not precluded. Such a pulsed laser deposition method will typically use a near stoichiometric (i.e., within about five percent atomic content variation) target with a varying background oxygen partial pressure.

Typically and preferably, such a pulsed laser deposition method will also use: (1) a reactor chamber pressure from about 10⁻⁸ to about 760 torr; (2) a substrate temperature from about 400 to about 1000 degrees centigrade; (3) an oxidant (i.e., typically oxygen) source material flow rate sufficient to provide: (a) an oxidant source material background pressure from about 10⁻⁸ to about 1 torr (or more preferably from about 10⁻³ to about 1 torr) for forming a perovskite crystal structure complex oxide material layer 12; or (b) an oxidant source material background pressure from about 10¹² to about 10⁻² torr (or more preferably from about 10⁻¹² torr to about 10⁻⁴ torr) for forming a perovskite crystal structure oxygen deficient complex oxide oxygen getter material layer 14 or 14′.

The chemical composition, and in particular the oxygen content within any of the foregoing substrate 10 or overlying complex oxide material layers 12, 12′, 14, 14′ and 14″ as illustrated in FIG. 1a to FIG. 1d may under certain circumstances be determined using any of several surface chemical analysis and surface sputtering methods and apparatus that are otherwise generally conventional in the surface micro-analysis art. Included but not limiting are electron spectroscopy for chemical analysis (ESCA) methods, Rutherford backscattering methods, Auger electron spectroscopy methods, and electron energy loss spectroscopy (EELS) methods.

### Experimental Examples

Discussed as follows are experimental exemplary results that were obtained at least in-part using in-situ synchrotron-based x-ray techniques for analyzing oxygen vacancy ordered phases in selected epitaxial manganite complex oxide material layers. The methodology involved deposition of a perovskite crystal structure oxygen deficient complex oxide oxygen getter material layer located and formed upon a stoichiometric perovskite crystal structure manganite complex oxide material layer. Once the perovskite crystal structure oxygen deficient complex oxide oxygen getter material layer exceeded a critical thickness, a crystal structure transformation to an oxygen vacancy ordered brownmillerite crystal structure superlattice complex oxide material layer initiated and occurred in the selected perovskite crystal structure manganite complex oxide material layers.

The experimental examples used perovskite crystal structure oxygen deficient strontium titanate (SrTiO_{3-δ} (STO)) and lanthanum-aluminum oxide (LaAlO_{3-δ} (LAO)) complex oxide material layers as perovskite crystal structure oxygen deficient complex oxide oxygen getter material layers to effect brownmillerite crystal structure superlattice formation in four different perovskite crystal structure complex oxide material layers: (1) La_{0.7}Sr_{0.3}MnO₃ (LSMO); (2) Pr_{0.7}Ca_{0.3}MnO₃ (PCMO); (3) La_{0.7}Ca_{0.3}MnO₃ (LCMO) and (4) LaMnO₃ (LMO). The resulting brownmillerite crystal structure superlattice complex oxide material layer heterostructures were maintained at ambient conditions after cooling to room temperature. It is contemplated that this particular heterostructure growth methodology may lead to the discovery of additional novel and technologically diverse crystal structure transformations of complex oxide materials that may not otherwise be realized by traditional deposition methodology.

Reflected high energy electron diffraction (RHEED) and x-ray scattering are commonly employed to monitor deposited layer thickness, roughness, morphology and structure during thin film complex oxide material layer deposition. The penetrating power of x-rays makes them uniquely suited for structural studies of the buried layers in heterostructures. To monitor deposited layer thickness during deposited layer or deposited structure deposition, a reflected x-ray intensity at an “anti-Bragg” crystallographic position may be monitored in real time. During homoepitaxial layer-by-layer growth, this anti-Bragg reflected x-ray intensity oscillates with a period corresponding with the deposition of one unit cell, as is described above as a unit cell monolayer (ML). For heteroepitaxial growth, the anti-Bragg reflected x-ray intensity oscillates with a period of either one monolayer or two monolayers, depending on a composition of the particular deposited layer heterostructure formed. The experimental examples in accordance with the embodiments used this anti-Bragg reflected x-ray intensity method and measured the intensity of specularly reflected x-rays at the (0½0) crystallographic position on the crystal truncation rod of a substrate (i.e., where [010] is the surface normal).

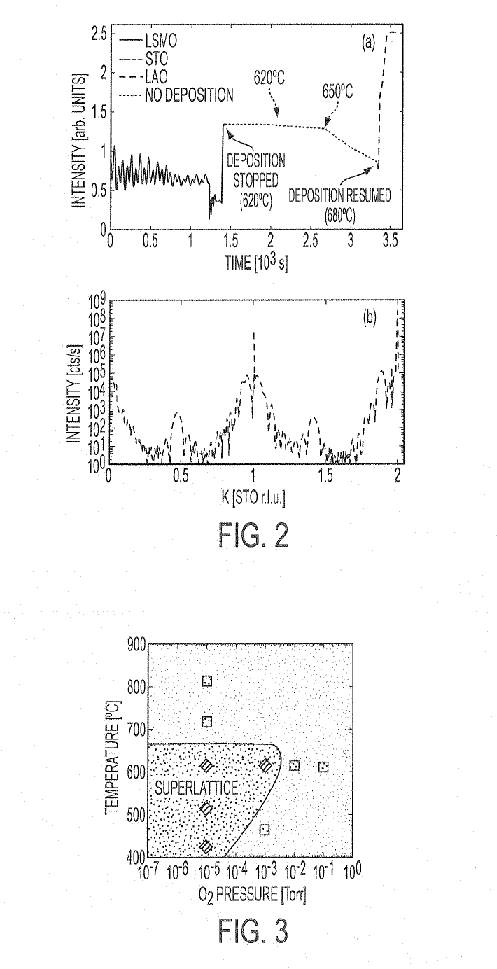

The anti-Bragg reflected x-ray intensity, which was measured during a pulsed laser deposition (PLD) of an LSMO/STO/LAO heterostructure located and formed upon a SrTiO₃(010) substrate, is shown in FIG. 2a. The reflected x-ray intensity oscillations during the perovskite crystal structure LSMO complex oxide material layer deposition correlate with the time period up to about 1250 seconds, and the time period between local maxima within this larger 1250 second time period corresponds approximately with deposition of each individual monolayer. The approximately 21.2 monolayers that comprise this perovskite crystal structure LSMO complex oxide material layer were deposited in 10 torr background pressure of oxygen (i.e., O₂) so that the deposited perovskite crystal structure LSMO complex oxide material layer was at least nearly fully oxygenated.

Next, approximately six monolayers of perovskite crystal structure oxygen deficient STO complex oxide oxygen getter material layer were located and formed upon a top surface of the perovskite crystal LSMO complex oxide material layer. The reflected x-ray intensity oscillations corresponding with the perovskite crystal structure oxygen deficient STO complex oxide oxygen getter material layer correspond with the time interval from about 1250 seconds to about 1300 seconds. The perovskite crystal structure oxygen deficient STO complex oxide oxygen getter material layer was deposited in 10⁻⁵ torr background pressure of oxygen.

Low angle annular dark field scanning transmission electron microscopy (STEM) of the deposited LSMO and STO complex oxide material layers deposited under the foregoing conditions showed that the resulting strain fields were similar to those reported previously (see, e.g. Muller et al. Nature, 430:657, 2004) confirming that the deposited STO complex oxide material layer was oxygen deficient. The perovskite crystal structure oxygen deficient STO complex oxide oxygen getter material layer was then capped with a perovskite crystal structure oxygen deficient LAO complex oxide oxygen getter material layer as illustrated, starting at about 1300 seconds in FIG. 2a, and again in 10⁻⁵ torr background pressure of oxygen, to assure an oxygen deficient composition.

After about six monolayers of the perovskite crystal structure oxygen deficient LAO complex oxide oxygen getter material layer were deposited, the reflected x-ray intensity increased abruptly. As is discussed below, the sharp and abrupt increase in reflected x-ray intensity is consistent with, and anticipated as due to, the formation of a brownmillerite crystal structure superlattice. This brownmillerite crystal structure superlattice has a lattice spacing that causes a Bragg reflection to form near the anti-Bragg position (0½0) of the substrate 10. Subsequent diffraction and microscopy measurements were undertaken and demonstrated that the brownmillerite crystal structure superlattice was located and formed in the buried LSMO complex oxide material layer only, rather than in the oxygen deficient STO or LAO complex oxide oxygen getter material layers, or in the bulk STO complex oxide substrate.

As illustrated in FIG. 2a, the formation of the brownmillerite crystal structure superlattice was dependent upon the continuous deposition of the perovskite crystal structure LAO complex oxide oxygen getter material layer. When the deposition of the perovskite crystal structure LAO complex oxide oxygen getter material layer was suspended, the brownmillerite crystal structure superlattice formation in the LMSO complex oxide material layer ceased and the anti-Bragg reflected x-ray intensity remained constant. If the resulting heterostructure was then heated (i.e., to about 650 degrees centigrade as illustrated in FIG. 2a), the reflected x-ray intensity began to decrease. When the perovskite crystal structure oxygen deficient LAO complex oxide oxygen getter material layer deposition was resumed (i.e., at about 3400 seconds as illustrated in'FIG. 2a), the reflected x-ray intensity began to increase again, until approximately 3500 seconds. At this point in time, the reflected x-ray intensity saturated and remained constant.

As discussed below, this reflected x-ray intensity, saturation is interpreted as corresponding to near-complete conversion of the as-deposited perovskite crystal structure LSMO complex oxide material layer from its as-deposited perovskite crystal structure to a brownmillerite crystal structure superlattice. Following the deposition, the resulting heterostructure was cooled to room temperature in about 1.5 hours in the same oxygen background pressure used for the depositing the perovskite crystal structure oxygen deficient STO and LAO complex oxide oxygen getter material layers. After the resulting heterostructure reached room temperature, the resulting heterostructure was stable in ambient atmospheric conditions.

Characteristics of the resulting brownmillerite superlattice heterostructure were determined by ex-situ x-ray specular reflectivity. The specular reflected x-ray intensity is plotted as a function of STO reciprocal lattice units (r.l.u.) in FIG. 2b. In addition to sharp (010) and (020) Bragg peaks from the STO substrate, deposited complex oxide material layer Bragg peaks and Kiessig thickness fringes are clearly evident. By fitting the (0½0) region to a simple finite-size line-shape, obtained was a periodicity of 8.2 Å and a deposited complex oxide material layer thickness of 77.5 Å. This deposited complex oxide material layer thickness was about three perovskite crystal structure LSMO unit cells less than the thickness obtained by counting the number of perovskite crystal structure LSMO complex metal oxide layer reflected x-ray intensity oscillations in FIG. 2a, suggesting that most, but not all, of the perovskite crystal structure LSMO complex oxide material layer is transformed into a brownmillerite crystal structure superlattice LSMO complex oxide material layer. The observed thickness of the buried layer superlattice measured by x-ray reflectivity was not consistent with conversion or transformation of either the STO or LAO perovskite crystal structure complex oxide oxygen getter material layers into a brownmillerite crystal structure superlattice. It was thus concluded that the ½-order peak as illustrated in FIG. 2b corresponds with a brownmillerite crystal structure superlattice in the LSMO complex oxide material layer only.

It is noted that since the brownmillerite crystal structure superlattice transformation occurs in the buried LSMO complex oxide material layer only, rather than at a surface of the heterostructure, the reflected x-ray intensity transition beginning at about 1400 seconds in FIG. 2a would not have been observed using conventional RHEED methodology, which probes only a near surface region of a heterostructure. Thus, reflected x-ray intensity scattering was critical for identifying this particular perovskite crystal structure to brownmillerite crystal structure LSMO complex oxide material layer transformation.

The brownmillerite crystal structure superlattice LSMO complex oxide material layer shown in FIG. 2a was formed with both perovskite crystal structure oxygen deficient STO and LAO complex oxide oxygen getter material layers as capping layers. However the foregoing perovskite crystal structure to brownmillerite crystal structure superlattice transformation for the LSMO complex oxide material layer may also be induced using only one deposited layer of either STO or LAO complex oxide as an oxygen deficient complex oxide oxygen getter material layer. To further investigate the conditions required to form the brownmillerite crystal structure superlattice, a series of identical perovskite crystal structure LSMO complex oxide material layers was deposited (615° C., 0.1 Torr O₂) and capped with a perovskite crystal structure oxygen deficient STO complex oxide oxygen getter material layer grown under varying conditions.

The results of the foregoing complex oxide material layer depositions are illustrated in FIG. 3. In this brownmillerite crystal structure superlattice transformation diagram, the lower left quadrant region represents the pressure and temperature regime where a perovskite crystal structure oxygen deficient STO complex oxide oxygen getter material layer induces the brownmillerite crystal structure superlattice transformation for an underlying perovskite crystal structure LSMO complex oxide material layer. The boundaries in the phase diagram represent approximate midpoints between data points. In accordance with FIG. 3, the brownmillerite crystal structure superlattice transformation for a perovskite crystal structure LSMO complex oxide material layer may occur at a temperatures as low as about 415° C. in 10E-5 torr oxygen background pressure, and as high as about 615° C. in 10E-3 torr oxygen background pressure, and as high as about 615° C. in 10E-3 torr oxygen background pressure.

In addition to the deposited layer conditions for the perovskite crystal structure oxygen deficient oxygen getter material layer indicated in FIG. 3, two additional conditions are anticipated as necessary to form and stabilize the embodied buried brownmillerite crystal structure superlattice transformation from a perovskite crystal structure LSMO complex oxide material layer.

First, the foregoing LSMO complex oxide material layer must be deposited under oxygen rich conditions, presumably to form at least a nearly stoichiometric perovskite crystal structure LSMO complex oxide material layer. Perovskite crystal structure LSMO complex oxide material layers deposited in 10⁻⁵ Torr O₂, followed by the deposition of a perovskite crystal structure oxygen deficient complex oxide oxygen getter material layer, do not exhibit relevant brownmillerite crystal structure superlattice peaks.

Second, after perovskite crystal structure LSMO complex oxide material layer deposition, increasing a partial pressure of oxygen while still at deposition temperature compromises the brownmillerite crystal structure superlattice transformation within a timescale of seconds. Thus, a post-deposition anneal in oxygen such as is frequently employed for forming robust complex oxide deposited layers eliminates the desirable brownmillerite crystal structure superlattice transformation in accordance with the embodiments, and such a post-deposition anneal must be avoided.

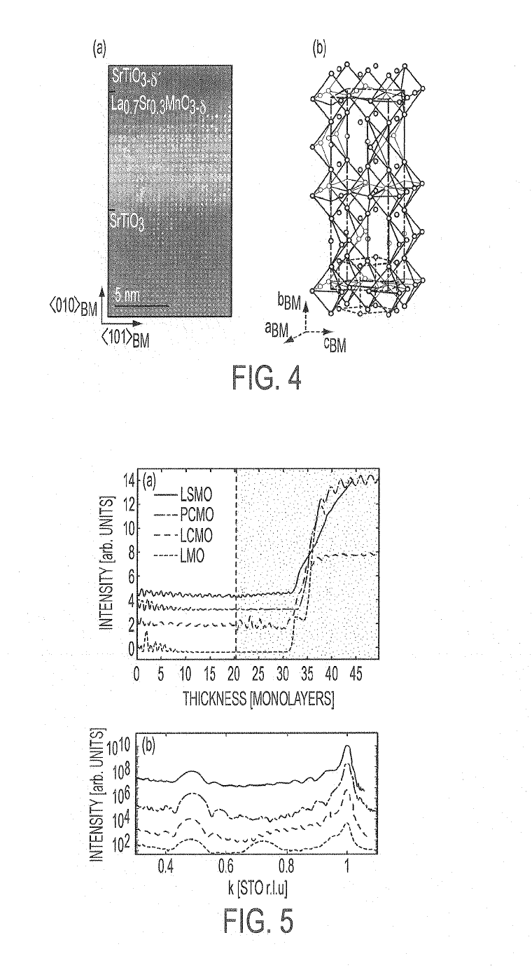

To examine the nature of the brownmillerite crystal structure superlattice, FIG. 4a shows a scanning transmission electron microscopy (STEM) image of the heterostructure formed in FIG. 2a. The high-angle annular dark field STEM image clearly shows a brownmillerite crystal structure superlattice of dark planes in the transformed LSMO complex oxide material layer, confirming the foregoing reflected x-ray intensity measurements. These dark planes coincide with the position of MnO₂ layers in a stoichiometric brownmillerite crystal structure LSMO complex oxide material layer, suggesting that the transformed LSMO complex oxide material layer is either manganese or oxygen deficient. These low density planes appeared in the transformed LSMO complex oxide material layer with a period of two perovskite unit cells. Since as illustrated in FIG. 3 the brownmillerite crystal structure superlattice LSMO complex oxide material layer formation is highly dependent upon the oxygen partial pressure, and annealing in a high oxygen content environment compromises the superlattice, a reasonable conclusion is that the dark planes result from missing oxygen rather than missing manganese cations.

Electron energy loss spectroscopy (EELS) measurements confirm the presence of Mn²⁺ ions, further supporting the foregoing conclusion. Presumably, since the perovskite crystal structure to brownmillerite crystal structure superlattice LSMO complex oxide material layer transformation occurs during deposition of an oxygen deficient complex oxide oxygen getter material layer, the formation of the superlattice may be driven by oxygen diffusion from the perovskite crystal structure LSMO complex oxide material layer into the perovskite crystal structure complex oxide oxygen getter material layer which serves as a capping layer. This analysis is consistent with similar observations (see, e.g., Takahashi et al., Appl. Phys. Lett., 93:082112, 2008) in which LaAlO₃ and LaTiO₃ overlayers were shown to extract oxygen from a buried anatase TiO₂ layer located and formed over an STO complex oxide material substrate.

In general, FIG. 4a correlates with other high resolution STEM images of brownmillerite crystal structure systems (see, e.g., Klenov et al. Appl. Phys. Lett., 82:3427, 2003 and Rossell et al. J. Appl. Phys., 95:5145, 2004). The brownmillerite family of crystal structures is associated with oxygen vacancy ordering in a perovskite crystal structure lattice. An idealized brownmillerite crystal structure is orthorhombic, has space group Pcmn, and is shown in FIG. 4b with the corresponding cubic perovskite crystal structure unit cell outlined at the bottom of the brownmillerite crystal structure unit cell. The perovskite crystal structure unit cell structure and the brownrnillerite crystal structure unit cell structure are rotated 45° from each other, and the unit cell parameters are related by: a_{BM}=c_{BM}≈\sqrt{2}a_{PV} and b_{BM}≈4a_{PV}. In this notation, the surface normal is in the [010] direction, the BM subscript refers to the brownrnillerite crystal structure system, and the PV subscript refers to the perovskite crystal structure system.

The brownmillerite crystal structure has BO₆ octahedra at the unit cell corners, with the oxygen vacancies ordering into missing rows oriented in the [100]_{BM} direction, causing the unit cell to alternate between oxygen octahedra and oxygen tetrahedral centered on the B cation sites. The missing rows of oxygen are shifted by a half unit cell in the c_{BM} direction for each half unit cell translation in the b_{BM} direction. Small rotations of the oxygen tetrahedra and octahedra can further distort the brownmillerite unit cell. Many of the resulting variants of the brownmillerite unit cell structure have been reported in bulk La₁₋ₓSrₓMnO₃ samples (see, e.g., T. G. Parsons et al. Chem. Mater., 21.5527, 2009). The (110)_{BM} Bragg peak corresponds approximately to (½¼½)_{PV} where the difference is due to the lattice mismatch between an STO complex oxide material substrate and the brownmillerite crystal structure LSMO complex oxide material layer. Ex-situ x-ray diffraction measurements (not shown) exhibit a weak reflection near (½¼½)_{PV} with four fold rotation symmetry about the surface normal, strongly consistent with a brownmillerite crystal structure. The measured out-of-plane lattice parameter is b_{BM}=16.47+0.01 Å. Since the in-plane lattice parameters are locked to an STO substrate, the measured lattice constant should not be identified as an equilibrium value.

To investigate whether this particular perovskite crystal structure to brownmillerite crystal structure LSMO complex oxide material layer transformation methodology is applicable to other complex oxide material layer systems, additional heterostructures were grown with LSMO, PCMO, LCMO, and LMO originally deposited as perovskite crystal structure complex oxide material layers. The anti-Bragg reflected x-ray intensity oscillations during the deposition of these heterostructures are shown in FIG. 5a. The deposition of the resulting AMnO₃ complex oxide material layers are presented against a lighter background, while a darker background is used to present a timescale for deposition of a perovskite crystal structure STO complex oxide oxygen getter material layer. The deposition temperatures of the AMnO₃ complex oxide material layers were 615° C., 850° C., 615° C., and 830° C. for the perovskite crystal structure LSMO, PCMO, LCMO and LMO complex oxide material layers, respectively. All four AMnO₃ complex oxide material layers were deposited to a thickness of about 20 monolayers, with a background oxygen pressure of 10⁻¹ torr for the LSMO, PCMO, and the LCMO complex oxide material layers. The LMO complex oxide material layer was deposited at 3×10⁻¹ torr oxygen background pressure. For each of the resulting heterostructures, the perovskite crystal structure STO complex oxide oxygen getter material layer was deposited at 615° C. in 10 torr oxygen background pressure.

All the foregoing manganite material heterostructures investigated exhibited the dramatic increase of the anti-Bragg reflected x-ray intensity, as illustrated in FIG. 5a (where the LSMO, PCMO, LCMO and LMO curves correspond, respectively, with the uppermost to the lowermost curves in the zero to thirty monolayer range). After cooling to room temperature, ex-situ reflected x-ray intensity measurements for each of the four heterostructures exhibited a (0½0) brownmillerite crystal structure superlattice peak, as shown in FIG. 5b (where the LSMO, PCMO, LCMO and LMO curves correspond, respectively, with the uppermost to the lowermost curves). The LMO complex oxide material layer showed an additional peak near (0¾0), indicating a further reduction in symmetry.

As illustrated in FIG. 5a, the perovskite crystal structure to brownrnillerite crystal structure transformations occur at approximately the same perovskite crystal structure STO complex oxide oxygen getter material layer thickness (i.e., about 12 monolayers) for all AMnO₃ complex oxide material layers. While not wishing to be bound by a particular theory of operation of the embodiments, plausibly this critical thickness of the perovskite crystal structure complex oxide oxygen getter material layer relates to a number of oxygen vacancies that must be obtained to reach a critical density in order to induce the perovskite crystal structure to brownmillerite crystal structure transformation.

In summary, the embodiments illustrate that a perovskite crystal structure oxygen deficient complex oxide oxygen getter material layer may be used to induce an oxygen vacancy ordered perovskite crystal structure to brownmillerite crystal structure superlattice transformation in buried manganite complex oxide material layers. The foregoing crystal structure transformation is apparently mediated by the diffusion of oxygen from the buried complex oxide material layer into the oxygen deficient complex oxide oxygen getter material layer. The methodology is demonstrated with LSMO, PCMO, LCMO, and LMO crystal structure transformed complex oxide material layers. Beyond the experimental exemplary embodiments, the embodiments may include other complex oxide material layer systems, as may be empirically determined.

Within the foregoing experimental examples, all deposited complex oxide material layers were deposited using a pulsed laser deposition apparatus that in turn used a KrF excimer laser (248 nm) at a repetition rate of 1 Hz. An appropriate complex oxide material layer target was spaced about 6 cm from a substrate. The substrate temperature was measured using an optical pyrometer (λ=4.8-5.3 μm, ε=0.8). To regulate the O₂ content within deposited complex oxide material layers, oxygen background pressure was controlled in the chamber atmosphere. The laser spots size on a particular target was 7.4 cm² for all deposited complex oxide material layers, with a fluence of 1.2 J cm⁻² for the LSMO, PCMO and LCMO deposited complex oxide material layers. The laser fluence was 1.6 J cm⁻² for the LMO deposited complex oxide material layer. The perovskite crystal structure STO and LAO complex oxide oxygen getter material layers were deposited with a fluence of 0.8 J cm⁻² and 1.6 J cm⁻², respectively. All complex oxide materials layers were deposited on SrTiO₃(010) substrates, prepared to have TiO₂ terminated surfaces using conventional methodology (see, e.g., G. Koster et al. Appl. Phys. Lett, 73:2920, 1998.). Atomic force microscopy (AFM) measurements ensured that substrates had unit cell high steps separated by large terraces. The in-situ reflected x-ray intensity measurements were performed in the pulsed laser deposition/x-ray diffraction system in the G3 experimental hutch at the Cornell, high energy synchrotron source (CHESS). The reflected x-ray intensity measurements shown in FIG. 2b were performed at the G2 hutch (ΔE/E=0.2%), while the data shown in FIG. 5b were collected at G3(ΔE/E=1.5%).

The embodiments and experimental examples of the invention are illustrative of the invention rather than limiting of the invention. Revisions and modifications may be made to methods, materials, structures and dimensions for a heterostructure and a method for forming the heterostructure in accordance with the embodiments and experimental examples, while still providing a heterostructure and a method for fabricating the heterostructure in accordance with the invention, further in accordance with the accompanying claims.

As is understood by a person skilled in the art, within the context of the above disclosure, all references, including publications, patent applications and patents cited herein are hereby incorporated by reference in their entireties to the extent allowed, and to the same extent as if each reference was individually and specifically indicated to be incorporated by reference and was set forth in its entirety herein.

The use of the terms “a” and “an” and “the” and similar referents in the context of describing the invention (especially in the context of the following claims) is to be construed to cover both the singular and the plural, unless otherwise indicated'herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is some other element intervening.

The recitation of ranges of values herein is merely intended to serve as an efficient method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary, language (e.g., “such as”) provided herein, is intended merely to better illuminate embodiments of the invention and does not impose a limitation on the scope of the invention unless otherwise indicated.

No language in the specification should be construed as indicating any non-claimed element as essential to the practice of the invention.

It will be thus further apparent to those skilled in the art that various modifications and variations can be made to the present invention without departing from the spirit and scope of the invention. There is no intention to limit the invention to the specific form or focus disclosed, but on the contrary, the intention is to cover all modifications, alternative constructions and equivalents falling within the spirit and scope of the invention, as defined in the appended claims. Thus, it is intended that the present invention cover the modifications and variations of this invention provided they come within the scope of the appended claims and their equivalents.

What is claimed is:

1. A heterostructure comprising:
a substrate;
a brownmillerite crystal structure first complex oxide material layer of composition A2B2O5 located upon the substrate; and
a perovskite crystal structure second complex oxide material layer of composition A′B′O3−δ′ located upon the first complex oxide material layer, where 3−δ′ is in a range from 1.5 to 3.0.

2. The heterostructure of claim 1 wherein the substrate comprises a perovskite crystal structure complex oxide material of composition A′B′O3.

3. The heterostructure of claim 1 wherein the A2B2O5 composition includes a range from A2B2O4.5 to about A2B2O5.5.

4. The heterostructure of claim 1 wherein:
A and A′ are different metal cations; and
B and B′ are different multivalent metal cations that are smaller than A and A′.

5. The heterostructure of claim 1 wherein the brownmillerite crystal structure first complex oxide material layer is selected from the group consisting of LSMO, PCMO, LCMO and LMO complex oxide material layers.

6. The heterostructure of claim 1 wherein the perovskite crystal structure second complex oxide material layer comprises a material layer selected from the group consisting of STO and LAO complex oxide material layers.

7. The heterostructure of claim 1 wherein 3−δ′ is in a range from 1.5 to 2.5.

8. The heterostructure of claim 1 wherein 3−δ′ is in a range from 1.5 to 2.0.

9. The heterostructure of claim 1 wherein the brownmillerite crystal structure first complex oxide material layer has a first thickness less than a second thickness of the perovskite crystal structure second complex oxide material layer.

10. The heterostructure of claim 9 wherein the first thickness is at least about 4 perovskite unit cell thicknesses.

11. The heterostructure of claim 1 wherein the perovskite crystal structure second complex oxide material layer has a greater affinity for oxygen than the brownmillerite crystal structure first complex oxide material layer.

12. A method for forming a heterostructure comprising:
forming over a substrate a perovskite crystal structure first complex oxide material layer having an ABO3 composition and a first thickness;
forming upon the perovskite crystal structure first complex oxide material layer a perovskite crystal structure second complex oxide oxygen getter material layer having an A′B′O3−δ composition, the perovskite crystal structure second complex oxide material layer having a second thickness such that one-half oxygen atom per perovskite crystal structure unit cell of the first complex oxide material layer is spontaneously extracted from the first complex oxide material layer to form:
a brownmillerite crystal structure first complex oxide material layer formed over the substrate and having a A2B2O5 composition; and
an oxygen enriched perovskite crystal structure second complex oxide oxygen getter material layer formed upon the brownmillerite crystal structure first complex oxide material layer and having an A′B′O3−δ′ composition, where 3−δ′ is greater than 3−δ.

13. The method of claim 12 wherein the substrate comprises a perovskite crystal structure complex oxide material of composition A′B′O3.

14. The method of claim 12 wherein the substantially A2B2O5 composition includes a range from about A2B204.5 to about A2B2O5.5.

15. The method of claim 12 wherein:
A and A′ are different metal cations; and
B and B′ are different multivalent metal cations that are smaller than A and A′.

16. The method of claim 12 wherein the forming the perovskite crystal structure first complex oxide material layer provides a perovskite first complex oxide material selected from the group consisting of LSMO, PCMO, LCMO and LMO perovskite first complex oxide materials.

17. The method of claim 12 wherein the forming the perovskite crystal structure second complex oxide material layer provides a perovskite second complex oxide material selected from the group consisting of STO and LAO perovskite second complex oxide materials.

18. The method of claim 12 wherein:
3−δ is in a range from 1.0 to 2.5; and
3−δ′ is in a range from 1.5 to 3.0.

19. The method of claim 12 wherein:
3−δ is in a range from 1.0 to 2.0; and
3−δ′ is in a range from 1.5 to 2.5.

20. The method of claim 12 wherein:
3−δ is in a range from 1.0 to 1.5; and
3−δ′ is in a range from 1.5 to 2.0.

21. The method of claim 12 wherein the forming the first complex oxide material layer and the forming the second complex oxide material layer uses an epitaxial laser pulse deposition method.

22. The method of claim 21 wherein:
the forming the first complex oxide material layer uses an oxygen background pressure from 1×10⁻⁸ to 1 torr; and
the forming the second complex oxide material layer uses an oxygen background pressure from 1×10-12 to 1×10-2 torr.
